(19) United States
(12) Patent Application Publication
(10) Pub. No.: US 2012/0170772 A1
(43) Pub. Date: Jul. 5, 2012

(54) METHOD AND APPARATUS FOR DYNAMICALLY ADJUSTING VOLUME

(76) Inventor: Huande Zheng, Shenzhen city (CN)

(21) Appl. No.: 13/395,335

(22) PCT Filed: Jun. 1, 2010
(86) PCT No.: PCT/CN2010/073418

§ 371 Date: Mar. 9, 2012

(30) Foreign Application Priority Data
Dec. 10, 2009 (CN) 2009101888067

(51) Int. Cl. H03G 3/00

(52) U.S. Cl. 381/107

(57) ABSTRACT

A method for dynamically adjusting volume is disclosed, which includes: determining dynamic adjustment step size I of output volume according to the preset time interval T of fading volume, the preset frequency F of fading volume, and the difference between the preset output volume V2 and the present output volume V1, and determining dynamic adjustment mode based on the step size I; determining the dynamic adjustment period of the present output volume in terms of the preset frequency F of fading volume; dynamically adjusting the present output volume to the preset the output volume V2 according to dynamic adjustment step size I and the dynamic adjustment mode when every dynamic adjustment period arrives. Correspondingly, an apparatus for dynamically adjusting volume is also disclosed. The invention enables the fade effect of the output volume during playing, pausing, stopping or dragging music etc. and the smooth effect of the volume transition during switching music or adjusting volume, making the music play smoother and mellower.

This application claims priority of Chinese Patent Application No. 2009101888067 titled “METHOD AND APPARATUS FOR DYNAMICALLY ADJUSTING VOLUME”, filed before the State Intellectual Property Office of the People's Republic of China on Dec. 10, 2009, and the entire contents of which are hereby incorporated by reference.

### FIELD OF THE INVENTION

The present application relates to multimedia technology, in particular, it relates to a method and apparatus for dynamically adjusting volume.

### BACKGROUND OF THE INVENTION

PCM (Pulse-code modulation) audio data is a digital method for analog signals. It divides the intensity of the signal into certain segments with the same space, and then quantified them through special digital marks (generally, binary bits). PCM is an audio data format supported by general sound cards.

To make the music playing smoother and mellower, generally the fading process of output volumes is needed during switching music. Existing solutions for fading process of output volumes are mainly used to perform attenuation coefficient process for original audio data, so as to achieve the fading of output volumes based on the fading of the coefficient. Because the original audio data (PCM code audio data) has its fixed filling formats in memory according to different bit rates, soundtracks and hertz, according to the formats the filled data of each format is taken and multiplied by an attenuation coefficient, and then smaller or larger sound than the original data will be obtained. The specific solution may refer to the following example: a solution on the fading of the output volume of the audio data of a section of 10 ms, 8 bits and 44100 Hz dimensional sound (double soundtracks).

The filled format of the audio data is shown in the table below:

| | Memory address | | | | | | | |
|---|---|---|---|---|---|---|---|---|
| | 0x410000 | | 0x410001 | | 0x410002 | | 0x410003 | |
| | Low bit | High bit | Low bit | High bit | Low bit | High bit | Low bit | High bit |
| Format | Left track | Right | Left track | Right | Left track | Right | Left track | Right |
| | | track | | track | | track | | track |
| Data | 0x80 | 0xAC | 0xE3 | 0x7D | 0x4E | 0x98 | 0x2C | 0x2C |

. . .

| | Memory address | | | | | | | |
|---|---|---|---|---|---|---|---|---|
| | 0x41036F | | 0x410370 | | 0x410371 | | 0x410372 | |
| | Low bit | High bit | Low bit | High bit | Low bit | High bit | Low bit | High bit |
| Format | Left track | Right | Left track | Right | Left track | Right | Left track | Right |
| | | track | | track | | track | | track |
| Data | 0xA0 | 0x5C | 0xB3 | 0x6D | 0x00 | 0x00 | 0xDC | 0xDC |

The volume of the 10 ms data can be reduced to 90% of the original volume through multiplying each data of the above section of the audio by a coefficient of 0.9.

It enables the fading-in effect during beginning to play music through multiplying the data of the beginning segment of the audio by a gradually larger coefficient from 0.0 to 1.0 in a segmented manner; it enables the fading-out effect before ending of playing music through multiplying the data of the ending segment of the audio by a gradually smaller coefficient form 1.0 to 0.0 in a segmented manner.

During implementing the present invention, the inventor discovers that the above solutions need fading process of coefficients in advance before the audio data being filled in a sound card to play in order to obtain the fading effect of the volume, therefore, it can only support the fading (fading-in and fading-out) process during naturally playing and stopping the audio, when users manually switch music, for example when users drag to change audio play progress or manually switch songs, it is difficult for the above solutions to make fadig process.

### SUMMARY OF THE INVENTION

The problem the present invention solved is to provide a method and an apparatus for dynamically adjusting volume. The invention enables the fading effect of the output volume during playing, pausing, stopping or dragging music etc. and the smooth effect of the volume transition during switching music or adjusting volume, making the music play smoother and mellower.

To solve the above problem, the embodiments of the present invention provide a method for dynamically adjusting volume which includes:

determining dynamic adjustment step size I of the present output volume according to the preset time interval T of fading volume, the preset frequency F of fading volume, and the difference between the preset output volume V2 and the present output volume V1, and determining dynamic adjustment mode based on the step size I;

determining the dynamic adjustment period of the present output volume in terms of the preset frequency F of fading volume;

dynamically adjusting the present output volume to the preset output volume V2 according to the dynamic adjustment step size I and the dynamic adjustment mode when every dynamic adjustment period arrives.

Correspondingly, the embodiments of the present invention also disclose an apparatus for dynamically adjusting volume which includes:

a first determination unit, for determining dynamic adjustment step size I of the present output volume according to the preset time interval T of fading volume, the preset frequency F of fading volume, and the difference between the preset output volume V2 and the present output volume V1, and determining dynamic adjustment mode based on the step size I;

a second determination unit, for determining the dynamic adjustment period of the present output volume in terms of the said preset frequency F of fading volume;

a timing unit, for timing the said dynamic adjustment period determined by the second determination unit;

a dynamic adjustment unit, for dynamically adjusting the present output volume to the preset output volume V2 according to the dynamic adjustment step size I and the dynamic adjustment mode determined by the first determination unit when every dynamic adjustment period timed by the timing unit arrives.

The invention doesn't need coefficient process for the audio data filled in a sound card in advance before playing, but dynamically adjusts the present output volume periodically and in equal quantity. It enables the fading effect of the output volume during playing, pausing, stopping or dragging music etc. and the smooth effect of the volume transition during switching music or adjusting volume, making the music play smoother and mellower.

### BRIEF DESCRIPTION OF THE DRAWINGS

FIG. 1 is a structure diagram showing an embodiment of an apparatus for dynamically adjusting volume of the present invention;

FIG. 2 is a structure diagram showing the first determination unit of an embodiment of an apparatus for dynamically adjusting volume of the present invention;

FIG. 3 is a structure diagram showing the dynamical adjustment unit of an embodiment of an apparatus for dynamically adjusting volume of the present invention;

FIG. 4 is a flow diagram showing the first embodiment of a method for dynamically adjusting volume of the present invention;

FIG. 5 is a diagram showing the fourth embodiment of a method for dynamically adjusting volume of the present invention;

FIG. 6 is a diagram showing volume change of the fourth embodiment of a method for dynamically adjusting volume of the present invention;

FIG. 7 is a diagram showing the fifth embodiment of a method for dynamically adjusting volume of the present invention.

### DETAILED DESCRIPTION OF THE PREFERRED EMBODIMENTS

The following detailed description is given with reference to the accompanying drawings to provide a thorough understanding of the embodiments of the present invention. Obviously, the described embodiments are merely part of the embodiments instead of all the embodiments of the present invention. All other embodiments, which can be derived by those skilled in the art from the embodiments given herein without any creative effort, shall fall within the protective scope claimed by the present invention.

Please refer to FIG. 1. FIG. 1 is a structure diagram showing an embodiment of an apparatus for dynamically adjusting volume of the present invention. As shown in FIG. 1, the apparatus includes: a first determination unit 10, a second determination unit 20, a timing unit 30 and a dynamic adjustment unit 40.

The first determination unit 10 is used for determining dynamic adjustment step size I of the present output volume according to the preset time interval T of fading volume, the preset frequency F of fading volume, and the difference between the preset output volume V2 and the present output volume V1, and determining dynamic adjustment mode based on the step size I.

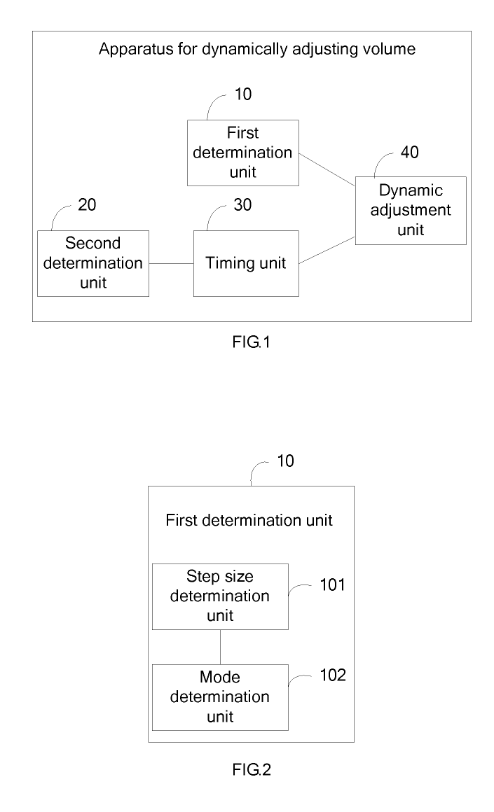

In particular, please refer to FIG. 2. FIG. 2 is a structure diagram showing the first determination unit of an embodiment of an apparatus for dynamically adjusting volume of the present invention. As shown in FIG. 2, the first determination unit 10 includes: a step size determination unit 101 and a mode determination unit 102.

The step size determination unit 101 is used for calculating dynamic adjustment step size I of the present output volume according to the formula of I=(V2−V1)/(T*F); in particular, for example, when beginning to play audio, the present output volume V1 is 0, and the preset time interval T of fading-in volume of the sound is supposed as 1000 ms, and the frequency F of fading-in volume is 1/10, i.e. the volume is changed by every 10 ms, and the output volume V2 preset by users is 100%, then according to the formula: I=(V2−V1)/(T*F)=(100%−0)/(1000/10)=1%, the calculated dynamic adjustment step size is 1%; another example, when stopping playing audio, the present output volume V1 of the present playing set by users is supposed as100%, and the volume when stopping playing, i.e. the preset output volume V2 is 0,and the preset time interval T of fading-out volume of the sound is supposed as 1000 ms, and the frequency F of fading-out volume is 1/10, i.e. the volume is changed by every 10 ms, then according to the formula: I=(V2−V1)/(T*F)=(0-100%)/(1000/10)=−1%, the calculated dynamic adjustment step size is −1%.

The mode determination unit 102 is used for determining the dynamic adjustment mode to be incremental adjustment when the step size I calculated by the step size determination unit 101 is a positive value, and determining the dynamic adjustment mode to be degressive adjustment when the step size I calculated by the step size determination unit 101 is a negative value. In particular, provided that the step size calculated by the formula as above is 1%, and the step size I is a positive value, and then the mode determination unit 102 can determine the dynamic adjustment mode to be incremental adjustment; provided that the step size calculated by the formula as above is −1%, and the step size I is a negative value, and then the mode determination unit 102 can determine the dynamic adjustment mode to be degressive adjustment.

In particular, the present output volumes are dynamically adjusted, wherein, the present output volumes include any one or more than one of the output volumes selected among from the output volume when beginning to play audio, the output volume when pausing or stopping audio, the output volume when changing the playing progress of audio, the output volume when switching songs and the output volume when changing the volume of audio.

The second determination unit 20 is used for determining the dynamic adjustment period of the present output volume in terms of the said preset frequency F of fading volume.

The timing unit 30 is used for timing the dynamic adjustment period determined by the second determination unit 20; in particular, the timing unit 30 is a timer, which sets the timing time in terms of the dynamic adjustment period, i.e., time once when every dynamic adjustment period arrives.

The dynamic adjustment unit 40 is used for dynamically adjusting the present output volume to the preset output volume V2 according to the dynamic adjustment step size I and the dynamic adjustment mode determined by the first determination unit 10 when every dynamic adjustment period timed by the timing unit 30 arrives.

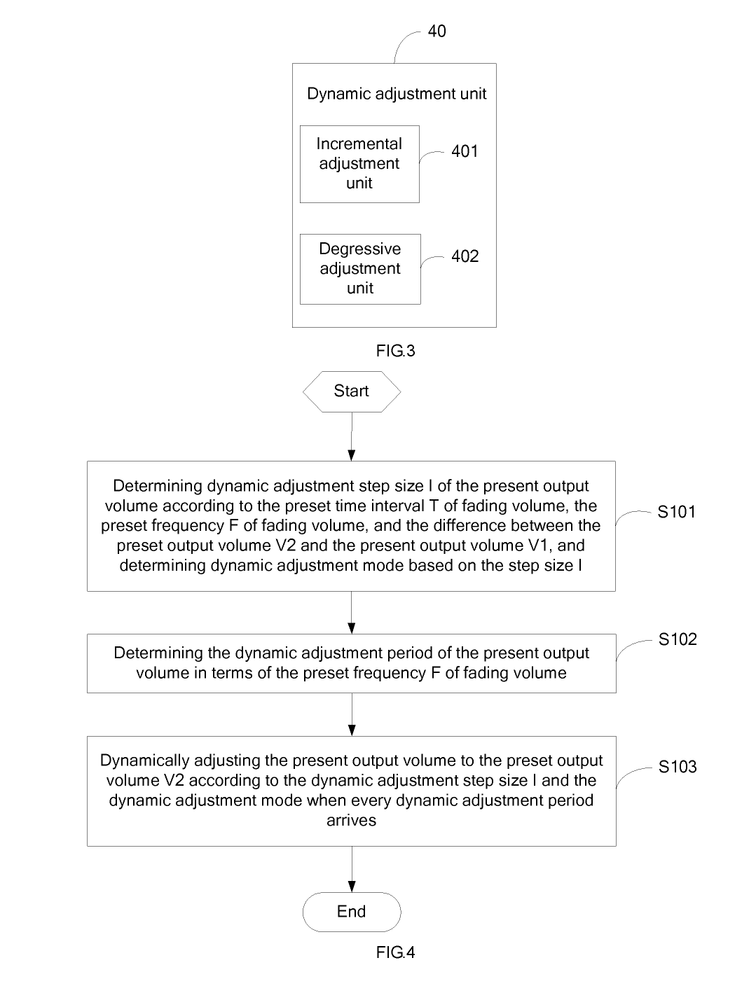

In particular, please refer to FIG. 3. FIG. 3 is a structure diagram showing the dynamical adjustment unit of an embodiment of an apparatus for dynamically adjusting volume of the present invention. As shown in FIG. 3, the dynamic adjustment unit 40 includes: incremental adjustment unit 401 and degressive adjustment unit 402.

The incremental adjustment unit 401 is used for increasing the present output volume by the absolute value of the step size I and then outputting the increased present output volume when every dynamic adjustment period timed by the timing unit 30 arrives, until the present output volume is adjusted to the preset output volume V2; in particular, as disclosed above, when beginning to play audio, the frequency F of fading-in volume is that the volume is changed by every 10 ms, and then it can be determined that the dynamic adjustment period is 10 ms, and the step size calculated by the formula is 1%, and the incremental adjustment unit 401 increases the present output volume by 1% and then outputs the increased present output volume when every 10 ms arrives, until the present output volume is adjusted to the preset output volume V2.

The degressive adjustment unit 402 is used for decreasing the present output volume by the absolute value of the step size I and then outputting the decreased present output volume when every dynamic adjustment period timed by the timing unit 30 arrives, until the present output volume is adjusted to the preset output volume V2; in particular, as disclosed above, when stopping playing audio, the frequency F of fading-out volume is that the volume is changed by every 10 ms, and then it can be determined that the dynamic adjustment period is 10 ms, and the step size calculated by the formula is −1%, and the degressive adjustment unit 402 decreases the present output volume by 1% and then outputs the decreased present output volume when every 10 ms arrives, until the present output volume is adjusted to the preset output volume V2.

In particular, dynamically adjusting volume is essentially the fading process of the volume which includes the fading-in process of the volume or the fading-out process of the volume. In general, the incremental adjustment unit 401 is used for the fading-in process of the volume, and the degressive adjustment unit 402 is used for the fading-out process of the volume.

The invention doesn't need coefficient process for the audio data filled in a sound card in advance before playing, but dynamically adjusts the present output volume periodically and in equal quantity. It enables the fading effect of the output volume during playing, pausing, stopping or dragging music etc. and the smooth effect of the volume transition during switching music or adjusting volume, making the music play smoother and mellower. In order to make the present invention more clearly, a detailed description about the flow of the apparatus for dynamically adjusting volume dynamically adjusting the present output volume is given below.

Please refer to FIG. 4. FIG. 4 is a flow diagram showing the first embodiment of a method for dynamically adjusting volume of the present invention. As shown in FIG. 4, the method includes:

S101, determining dynamic adjustment step size I of the present output volume according to the preset time interval T of fading volume, the preset frequency F of fading volume, and the difference between the preset output volume V2 and the present output volume V1, and determining dynamic adjustment mode based on the step size I;

In particular, the step S101 includes:

calculating dynamic adjustment step size I of the present output volume according to the formula of I=(V2−V1)/(T*F);

when the said step size I is a positive value, determining the dynamic adjustment mode to be incremental adjustment;

when the said step size I is a negative value, determining the dynamic adjustment mode to be degressive adjustment.

S102, determining the dynamic adjustment period of the present output volume in terms of the preset frequency F of fading volume;

S103, dynamically adjusting the present output volume to the preset output volume V2 according to the dynamic adjustment step size I and the dynamic adjustment mode when every dynamic adjustment period arrives.

In particular, the step S103 includes:

increasing the present output volume by the absolute value of the step size I and then outputting the increased present output volume when every dynamic adjustment period arrives, until the present output volume is adjusted to the preset output volume V2. or,

decreasing the present output volume by the absolute value of the step size I and then outputting the decreased present output volume when every dynamic adjustment period arrives, until the present output volume is adjusted to the preset output volume V2.

In particular, the present output volumes are dynamically adjusted, wherein, the present output volumes include any one or more than one of the output volumes selected among from the output volume when beginning to play audio, the output volume when pausing, stopping audio, the output volume when changing the playing progress of audio, the output volume when switching songs and the output volume when changing the volume of audio. Wherein, dynamically adjusting volume is essentially the fading process of the volume which includes the fading-in process of the volume or the fading-out process of the volume. In general, incrementally adjusting volume is the fading-in process of the volume, and degressively adjusting volume is the fading-out process of the volume.

The invention doesn't need coefficient process for the audio data filled in a sound card in advance before playing, but dynamically adjusts the present output volume periodically and in equal quantity. It enables the fading effect of the output volume during playing, pausing, stopping or dragging music etc. and the smooth effect of the volume transition during switching music or adjusting volume, making the music play smoother and mellower.

In order to disclose the present invention more clearly, a detailed description about embodiments of dynamically adjusting various present output volumes is given below.

The second embodiment of a method for dynamically adjusting volume of the present invention is given below, and the embodiment is the fading-in process of the output volume when beginning to play audio.

When users select to begin to play music, firstly the present output volume V1 is set as 0, and the preset time interval T of fading-in volume of the sound is supposed as 1000 ms, and the frequency F of fading-in volume is 1/10, i.e. the volume is changed by every 10 ms, and the output volume V2 preset by users is 100%, then according to the formula: I=(V2−V1)/(T*F)=(100%−0)/(1000/10)=1%, and then it is need to increase the present output volume by 1% every 10 ms, therefore, a 10 ms interval timer is adopted, and the present output volume of the sound is changed when the time timed by the timer arrives, so that the present output volume is increased by 1% volume when every 10 ms arrives until the present output volume achieves 100% volume preset by users.

The invention doesn't need coefficient process for the audio data filled in a sound card in advance before playing, but dynamically adjusts the present output volume periodically and in equal quantity. It enables the fading-in effect of the output volume when beginning to play music, making the music play smoother and mellower.

The third embodiment of a method for dynamically adjusting volume of the present invention is given below, and the embodiment is the fading-out process of the output volume when pausing or stopping audio.

When users select to pause or stop playing music, the preset time interval T of fading-out volume of the sound is supposed as 1000 ms, and the frequency F of fading-out volume is 1/10, i.e. the volume is changed by every 10 ms, and users set the present output volume V1 of the present playing as 100%, and the preset output volume V2 is 0, then according to the formula: I=(V2−V1)/(T*F)=(0-100%)/(1000/10)=−1%, and then it is need to decrease the present output volume by 1% every 10 ms, therefore, a 10 ms interval timer is adopted, and the present output volume of the sound is changed when the time timed by the timer arrives, so that the present output volume is decreased by 1% volume when every 10 ms arrives until the present output volume achieves 0.

If it is a normal end of a song instead of stopping playing chosen by users, the fading-out process can be adopted at 1000 ms before the end of the song. For example, provided the time interval of the audio is 30 s (30000 ms), and the preset fading-out time interval is 1000 ms, and then the fading-out process is started when the song is played at its 29 s (29000 ms).

The invention doesn't need coefficient process for the audio data filled in a sound card in advance before playing, but dynamically adjusts the present output volume periodically and in equal quantity. It enables the fading-out effect of the output volume during pausing or stopping music, making the music play smoother and mellower.

Please refer to FIG. 5. FIG. 5 is a diagram showing the fourth embodiment of a method for dynamically adjusting volume of the present invention, and the embodiment is about the fading-out process and the fading-in process of the output volume when changing the playing progress.

As shown in FIG. 5, segment A-E is circular buffer of sound, W is the write-in position of audio data, the audio data are filled in from A to E, and after the buffer being full, then get back to A to continue to fill data until to E, and so on; P is the reading data position of the playing of a sound card, the output of the sound card reads data from A to E, and after the data of the buffer being played, then get back to A to continue to read data until to E.

Provided that data are filled at to C and are read at to A, users change the playing progress at this moment and desire to listen to the music at another playing progress, now provided the circular buffer of the sound card store 1000 ms of the audio data, i.e. playing the audio data of segment A-E needs 1000 ms. When users dragging, provided the time interval T of fading-out volume is needed to be 300 ms, and it can be calculated that the playing just stops at B when starts at A and continues for 300 ms, i.e. the audio data of segment A-B are the sound for fading-out, at the moment it is able to position the write-in position W at B, and write in new audio data of after the playing progress having been changed from B; provided the time interval T of fading-in volume is needed to be 500 ms, and it can be calculated that the playing just stops at D when starts at B and continues for 500 ms, i.e. the audio data of segment B-D are the sound for fading-in.

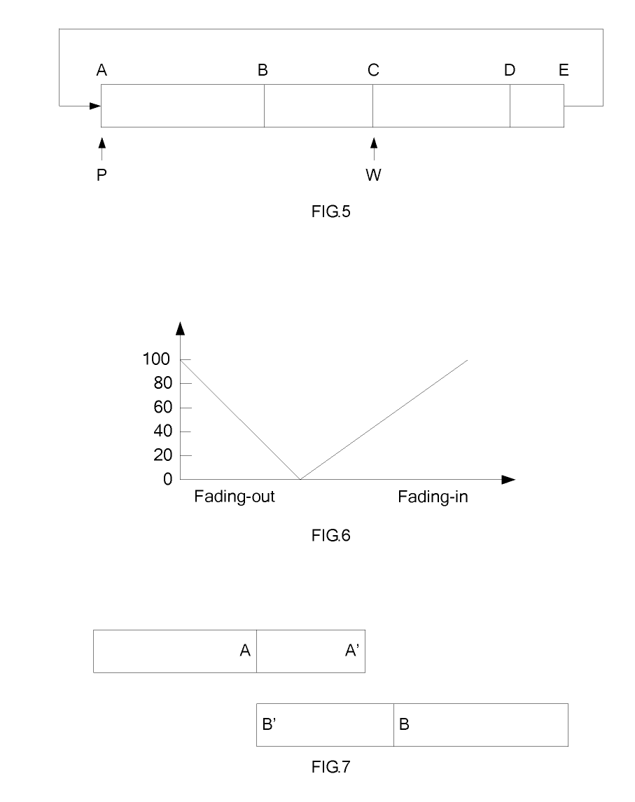

After the fading-out and fading-in data being determined, like the implementation as the two above embodiments, when users changing the progress, firstly 300 ms of the fading-out is carried out on the audio data of segment A-B that is presently playing, and the step size of the decreased volume during the fading-out is determined based on the settings. The fading-in of the volume starts when the output volume arrives at 0, and the step size of the increased volume during the fading-in is determined based on the settings at the time of the audio data of segment B-D being played, so that the output volume is increased to the preset volume by users. Please refer to FIG. 6. FIG. 6 is a diagram showing volume change of the fourth embodiment of a method for dynamically adjusting volume of the present invention. In FIG. 6, the vertical ordinate is volume coordinate, and the horizontal ordinate is time coordinate (corresponding to the changed progress by users); it can be seen from FIG. 6 that, when changing the play progress, the music play will be smoother after being switched to new audio data.

The invention doesn't need coefficient process for the audio data filled in a sound card in advance before playing, but dynamically adjusts the present output volume periodically and in equal quantity. It enables the fading effect of the output volume during dragging music, making the music play smoother and mellower.

Please refer to FIG. 7. FIG. 7 is a diagram showing the fifth embodiment of a method for dynamically adjusting volume of the present invention. The embodiment is about the cross-integrating process of the fading-out and the fading-in when switching music.

In some music players, each song is played in its own independent thread, such as QQ music, when users switch song A to song B, like the above embodiments, the thread of song A will end the sound of song A in fading-out way during ending song A, and at the same time, the thread of song B will begin to play song B in fading-in way. As shown in FIG. 7, in the thread of song A, segment A′ is fading-out, and in the thread of song B, segment B′ is fading-in.

Circular buffers of sound are independent from each other, and the volume settings for the buffers are also independent from each other, therefore it enables the cross-integrating effect that the sound of song A is fading-out and the sound of song B is fading-in simultaneously.

The invention doesn't need coefficient process for the audio data filled in a sound card in advance before playing, but dynamically adjusts the present output volume periodically and in equal quantity. It enables the smooth effect of the volume transition during switching music, making the music play smoother and mellower.

It should be understood that the above are only exemplary embodiments of the present invention, other embodiments can be analyzed similarly, for example: when users change volume, such as the cases that the fading-out process during decreasing the volume and the fading-in process during increasing the volume, a similar analysis can be carried out, and the description will not repeated again.

The invention doesn't need coefficient process for the audio data filled in sound card in advance before playing, but dynamically adjusts the present output volume periodically and in equal quantity. It enables the fading effect of the output volume during playing, pausing, stopping or dragging music etc. and the smooth effect of the volume transition during switching music or adjusting volume, making the music play smoother and mellower.

The above descriptions are merely some exemplary embodiments of the present invention, but are not intended to limit the scope of the present invention. Any modifications, variations or replacements that can be easily derived by those skilled in the art shall fall within the scope of the present invention.

1. A method for dynamically adjusting volume, the method comprising:
determining dynamic adjustment step size I of the present output volume according to the preset time interval T of fading volume, the preset frequency F of fading volume, and the difference between the preset output volume V2 and the present output volume V1, and determining dynamic adjustment mode based on the step size I;
determining the dynamic adjustment period of the present output volume in terms of the preset frequency F of fading volume;
dynamically adjusting the present output volume to the preset output volume V2 according to the dynamic adjustment step size I and the dynamic adjustment mode when every dynamic adjustment period arrives.

2. The method according to claim 1, the said determining dynamic adjustment step size I of output volume according to the preset time interval T of fading volume, the preset frequency F of fading volume, and the difference between the preset output volume V2 and the present output volume V1, and determining dynamic adjustment mode based on the step size I, comprising:
calculating dynamic adjustment step size I of the present output volume according to the formula of I=(V2−V1)/(T*F);
when the said step size I is a positive value, determining the dynamic adjustment mode to be incremental adjustment;
when the said step size I is a negative value, determining the dynamic adjustment mode to be degressive adjustment.

3. The method according to claim 2, when the said dynamic adjustment mode is determined to be incremental adjustment, the said dynamically adjusting the present output volume to the preset output volume V2 according to the dynamic adjustment step size I and the dynamic adjustment mode when every dynamic adjustment period arrives comprising:
increasing the present output volume by the absolute value of the step size I and then outputting the increased present output volume when every dynamic adjustment period arrives, until the present output volume is adjusted to the preset output volume V2.

4. The method according to claim 2, when the said dynamic adjustment mode is determined to be degressive adjustment, the said dynamically adjusting the present output volume to the preset output volume V2 according to the dynamic adjustment step size I and the dynamic adjustment mode when every dynamic adjustment period arrives comprising:
decreasing the present output volume by the absolute value of the step size I and then outputting the decreased present output volume when every dynamic adjustment period arrives, until the present output volume is adjusted to the preset output volume V2.

5. The method according to claim 1, the said present output volume comprises:
any one or more than one of the output volumes selected among from the output volume when beginning to play audio, the output volume when pausing or stopping audio, the output volume when changing the playing progress of audio, the output volume when switching songs and the output volume when changing the volume of audio.

6-8. (canceled)

9. The method according to claim 2, the said present output volume comprises:
any one or more than one of the output volumes selected among from the output volume when beginning to play audio, the output volume when pausing or stopping audio, the output volume when changing the playing progress of audio, the output volume when switching songs and the output volume when changing the volume of audio.

10. The method according to claim 3, the said present output volume comprises:
any one or more than one of the output volumes selected among from the output volume when beginning to play audio, the output volume when pausing or stopping audio, the output volume when changing the playing progress of audio, the output volume when switching songs and the output volume when changing the volume of audio.

11. The method according to claim 4, the said present output volume comprises:
any one or more than one of the output volumes selected among from the output volume when beginning to play audio, the output volume when pausing or stopping audio, the output volume when changing the playing progress of audio, the output volume when switching songs and the output volume when changing the volume of audio.

12. An apparatus for dynamically adjusting volume, the apparatus comprising:
a first determination unit, for determining dynamic adjustment step size I of the present output volume according to the preset time interval T of fading volume, the preset frequency F of fading volume, and the difference between the preset output volume V2 and the present output volume V1, and determining dynamic adjustment mode based on the step size I;
a second determination unit, for determining the dynamic adjustment period of the present output volume in terms of the said preset frequency F of fading volume;
a timing unit, for timing the dynamic adjustment period determined by the second determination unit;
a dynamic adjustment unit, for dynamically adjusting the present output volume to the preset output volume V2 according to the dynamic adjustment step size I and the dynamic adjustment mode determined by the first determination unit when every dynamic adjustment period timed by the timing unit arrives.

13. The apparatus according to claim 12, the first determination unit comprising:
a step size determination unit, for calculating dynamic adjustment step size I of the present output volume according to the formula of I=(V2−V1)/(T*F);
a mode determination unit, for determining the dynamic adjustment mode to be incremental adjustment when the said step size I calculated by the step size determination unit is a positive value, and determining the dynamic adjustment mode to be degressive adjustment when the said step size I calculated by the step size determination unit is a negative value.

14. The apparatus according to claim 13, the dynamic adjustment unit comprising:
an incremental adjustment unit, for increasing the present output volume by the absolute value of the step size I and then outputting the increased present output volume when every dynamic adjustment period timed by the timing unit arrives, until the present output volume is adjusted to the preset output volume V2;
a degressive adjustment unit, for decreasing the present output volume by the absolute value of the step size I and then outputting the increased present output volume when every dynamic adjustment period timed by the timing unit arrives, until the present output volume is adjusted to the preset output volume V2.
